(19) United States
(12) Patent Application Publication
(10) Pub. No.: US 2014/0004677 A1
(43) Pub. Date: Jan. 2, 2014

(54) High-k Seal for Protection of Replacement Gates

(71) Applicants: Ying Li, Newburgh, NY (US); Raymond Joy, Hopewell Junction, NY (US); Yong Meng Lee, Hopewell Junction, NY (US)

(72) Inventors: Ying Li, Newburgh, NY (US); Raymond Joy, Hopewell Junction, NY (US); Yong Meng Lee, Hopewell Junction, NY (US)

(73) Assignees: GLOBALFOUNDRIES, INC., Grand Cayman (KY); INTERNATIONAL BUSINESS MACHINES CORPORATION, ARMONK, NY (US)

(21) Appl. No.: 13/537,140

(22) Filed: Jun. 29, 2012

(51) Int. Cl. H01L 21/336; H01L 21/20

(52) U.S. Cl. 438/299; 438/478; 257/E21.09; 257/E21.409

(57) ABSTRACT

Embodiments of the invention include methods of protecting sacrificial gates during raised/source drain and replacement metal gate processes. Embodiments include steps of forming sacrificial gates on a semiconductor substrate, protecting the sacrificial gates with gate seals, forming source/drains near the sacrificial gates without substantially growing semiconductor material on the sacrificial gates, removing the gate seals, and replacing the sacrificial gates with metal gates. In some embodiments, the gate seals are made of a high-k material.

### BACKGROUND

The present invention generally relates to semiconductor devices, and particularly to a method of forming microelectronic devices using a high-k layer to protect gate structures.

As developments in semiconductor technology continue to shrink the size of microelectronic structures, defects due to dimensional irregularities become more common. One example of this occurs in devices that utilize replacement metal gate and raised source/drain technologies. The replacement gate technology utilizes a sacrificial gate, typically made of silicon, which defines the region where a metal gate is later deposited during preceding manufacturing processes. Raised source/drains (RSDs) consist of epitaxially grown silicon regions formed on a semiconductor substrate adjacent to gates. RSDs allow for, among benefits, improved silicide and contact formation by elevating the top surface of the source/drain above the surface of the substrate. However, the additional process of growing epitaxial silicon in RSD regions introduces the potential for additional defects caused by silicon growth in undesirable regions. One example of such an undesirable region is a silicon sacrificial gate. To avoid epitaxial growth on silicon sacrificial gates, protective layers containing, for example, oxides and/or nitrides may be deposited over the sacrificial gates prior to the period of epitaxial growth. However, subsequent processes, such as reactive ion etching, can unintentionally remove these protective layers and expose the sacrificial gate. The resulting epitaxial growth on the exposed sacrificial gate is an undesirable defect that may cause device failure due to problems such as shorting to adjacent surfaces. To prevent such defects, thick protective layers as well as overlap of such layers at N-type transistor to P-type transistor transition areas may be utilized to ensure sacrificial gate protection during epitaxial growth. As the critical dimensions of semiconductor devices become smaller, thick protective layers not only creates challenges for dielectric fill between gates but also results in uneven gates which makes chemical mechanical polishing (CMP) of sacrificial metal gates extremely difficult and affects yield. Therefore, a method of preventing the growth of epitaxial silicon on sacrificial gates during raised source/drain formation without employing thick, overlapped protective layers may lead to increased device reliability and yield.

### BRIEF SUMMARY

The present invention relates to a method of forming a semiconductor device. One embodiment of the present invention may include first, forming a sacrificial gate material layer and a gate protection layer on the surface of a semiconductor substrate then etching the sacrificial gate material layer and the gate protection layer to form sacrificial gates made of portions of the sacrificial gate material layer with a top surface protected by gate seals made of gate protection layer. In one embodiment, the gate protection layer comprises a high-k material. Source/drains are then formed near the sacrificial gates while the sacrificial gates are protected by the gate seals. The gate seals are then removed and the sacrificial gates are replaced by metal gates including at least one metal liner and a metal film. In one embodiment, the source/drains may be formed by etching recess regions in the semiconductor substrate and then epitaxially growing semiconductor material in the recess regions without substantially growing semiconductor material on the sacrificial gates.

### BRIEF DESCRIPTION OF THE SEVERAL VIEWS OF THE DRAWINGS

FIGS. 1-16 are vertical cross-sectional views of a semiconductor structure with sacrificial gates protected by a high-k seal that illustrate a method of manufacturing the structure according to at least one exemplary embodiment.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying figures, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

While the present invention has been particularly shown and described with respect to preferred embodiments, it will be understood by those skilled in the art that changes in forms and details may be made without departing from the spirit and scope of the described embodiments. It is therefore intended that the present invention not be limited to the exact forms and details described and illustrated but fall within the scope of the appended claims.

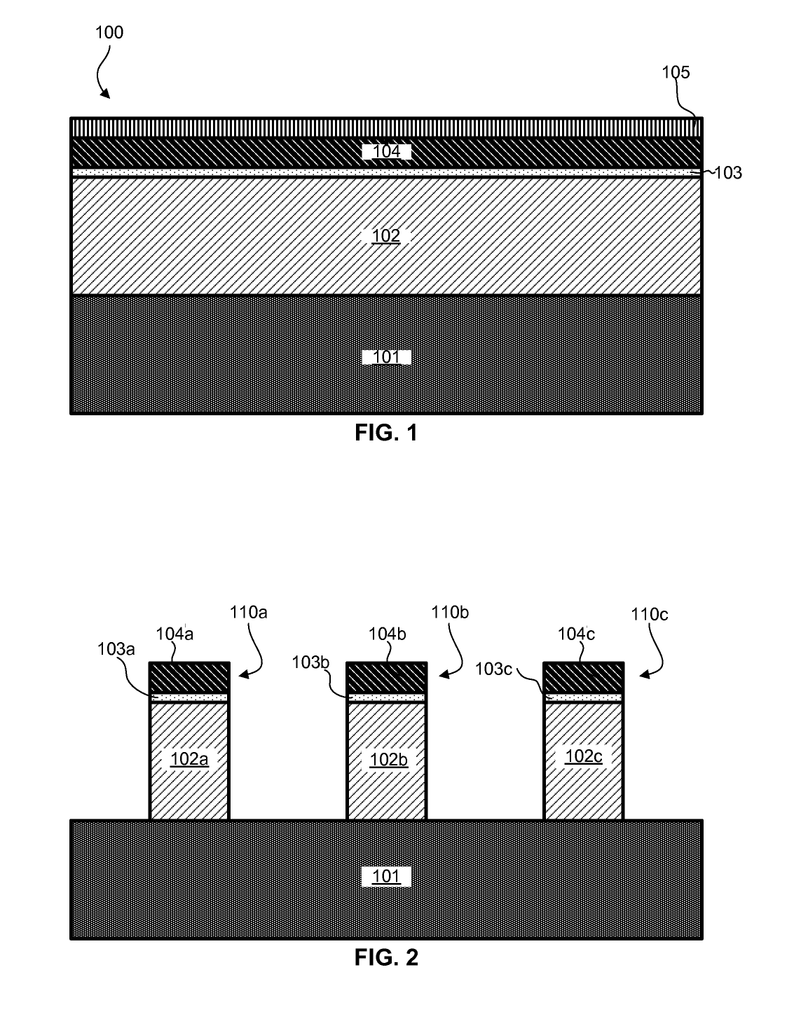

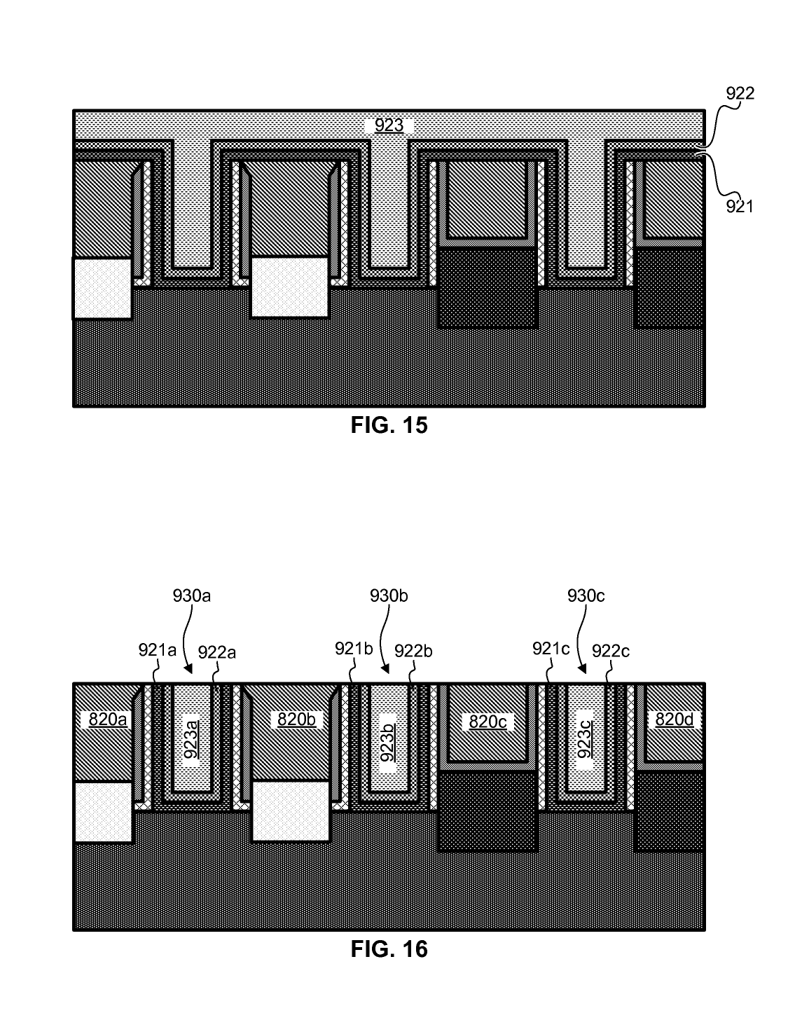

Referring to FIG. 1, a layer stack 100 may be provided including, but not limited to, gate layer 102, gate protection layer 103, first hard mask layer 104, and second hard mask layer 105. Substrate 101 may be made of any semiconductive material including, but not limited to, silicon, silicon on insulator, silicon-germanium, and silicon carbide, and may or may not include doped regions (not shown). Substrate 101 may be 5 nm to hundreds of microns thick. Sacrificial gate layer 102 may be made of polysilicon or silicon and may be 15 nm to 200 nm thick, preferably 30 nm to 100 nm. Gate protection layer 103 may be made of a material possessing a high dielectric constant (“high-k material”) including, but not limited to, hafnium oxide, hafnium oxynitrate, and aluminum oxide, and may be 2 nm to 15 nm thick, preferably approximately 5 nm thick. First hard mask layer 104 may be made of a nitride or oxide material, for example silicon nitride or silicon oxide, and may be 5 nm to 150 nm thick, preferably 15 nm to 90 nm. Second hard mask layer 105 may be made of a nitride or oxide material, for example silicon nitride or silicon oxide, and may be 5 nm to 150 nm thick, preferably 15 nm to 90 nm. Layer stack 100 may be made by any known methods in the art. A gate dielectric layer (not shown) may be deposited between substrate 101 and sacrificial gate layer 102. Alternatively, the gate dielectric layer may be formed by oxidation of substrate 101, or formed by the replacement metal gate process depicted in FIGS. 14-15. A person of ordinary skill in the art will understand how to incorporate a gate dielectric layer or other additional features into the embodiment without departing from its scope.

Referring to FIG. 2, layer stack 100 (FIG. 1) is patterned and etched to form a series of gates 110a-110c. Photolithography and known etching processes, such as reactive ion etching (RIE) may be used to first pattern second hard mask layer 105. Further etching processes may then be used to transfer the pattern of second hard mask layer 105 into first hard mask layer 104, gate protection layer 103, and sacrificial gate layer 102 to form hard masks 104a-104c, from gate protection layer 103 to form gate seals 103a-103c, and from sacrificial gate layer 102 to form sacrificial gates 102a-102c. Any remaining material of second hard mask layer 105 may then be removed.

Referring to FIG. 3, a first spacer material layer 210 is deposited on the surface of each gate 110a-110c and the exposed top surface of substrate 101. Spacer material layer 210 may be made of materials including, but not limited to, silicon nitride, silicon oxide, silicon carbide and may be 2 nm to 100 nm thick, preferably 2 nm to 50 nm.

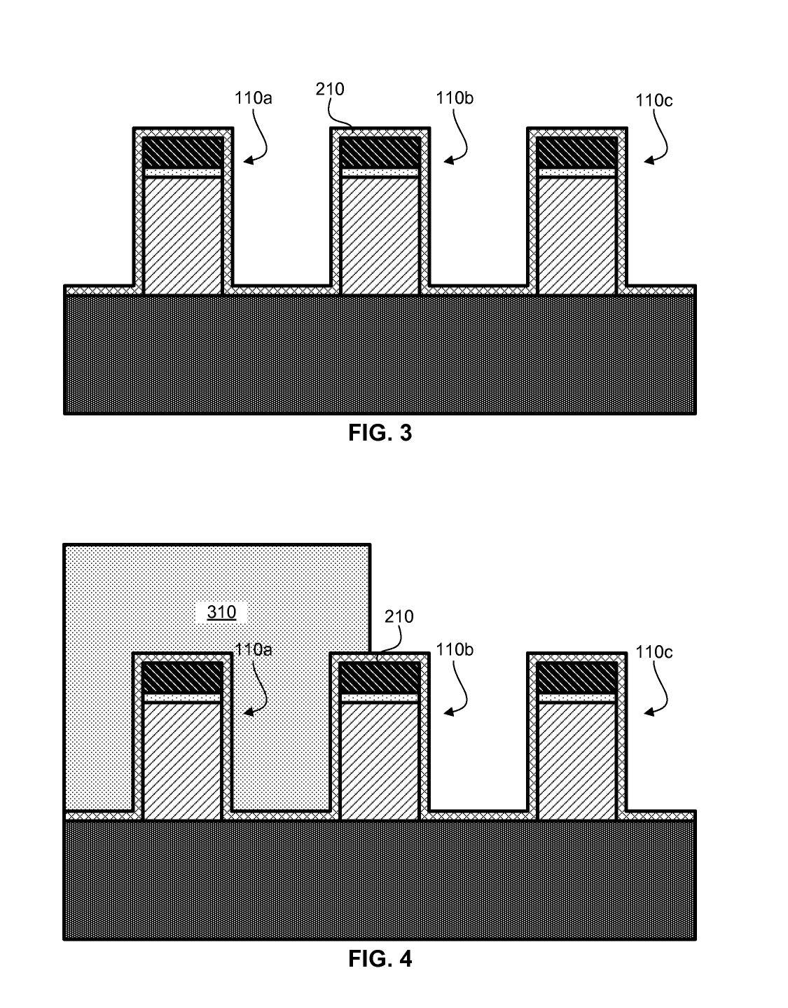

Referring to FIG. 4, a first photoresist layer 310 is deposited, patterned, and formed over the left side of the structure of FIG. 3, so that gate 110a is fully covered and gate 110b is partially covered by first photoresist layer 310. In one embodiment, gate 110b is less than fifty percent covered. Gate 110c remains exposed.

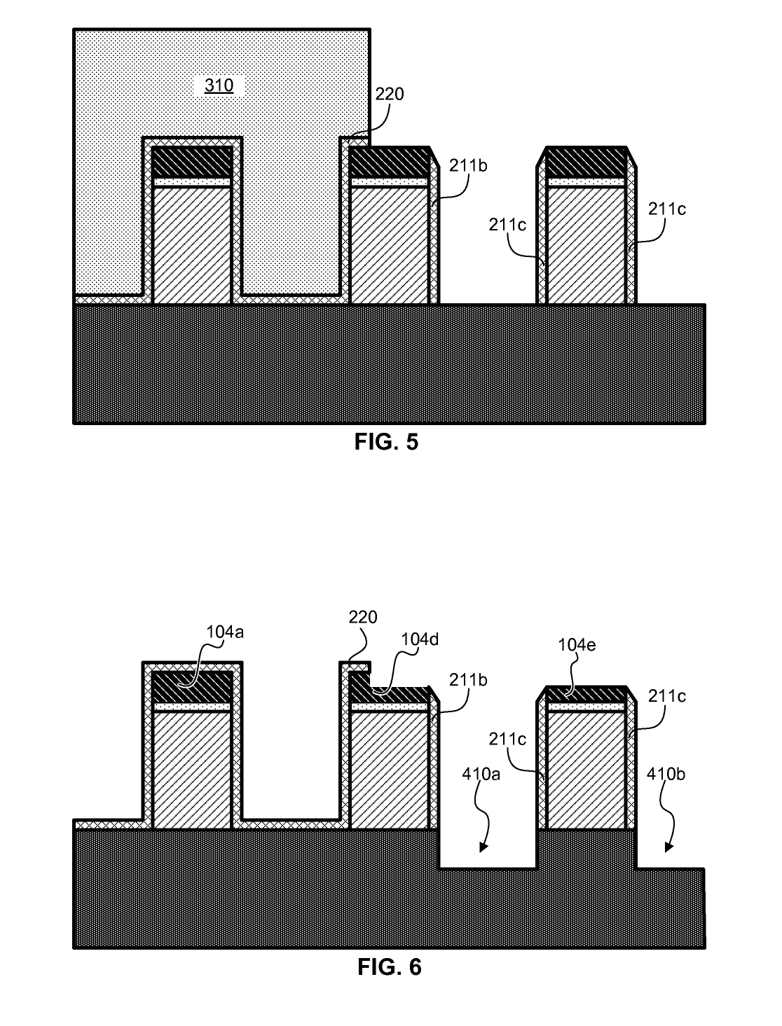

Referring to FIG. 5, spacers 211b and 211c are formed on the sides of gates 110b and 110c, respectively, by an etching process, for example RIE, that removes material from first spacer material layer 210. During the etching process, the portion 220 of first spacer material layer 210 covered by first photoresist layer 310 is protected. After the etching process, first photoresist layer 310 is removed (not shown).

Referring to FIG. 6, the portion of the structure of FIG. 5 not covered by portion 220 is etched, using, for example, RIE, to form source/drain recess regions 410a and 410b. During the etching process, material may also be removed from spacers 211b and 211c, and the exposed top surfaces of hard masks 104b and 104c (FIG. 5) to form hard mask segments 104d and 104e, respectively.

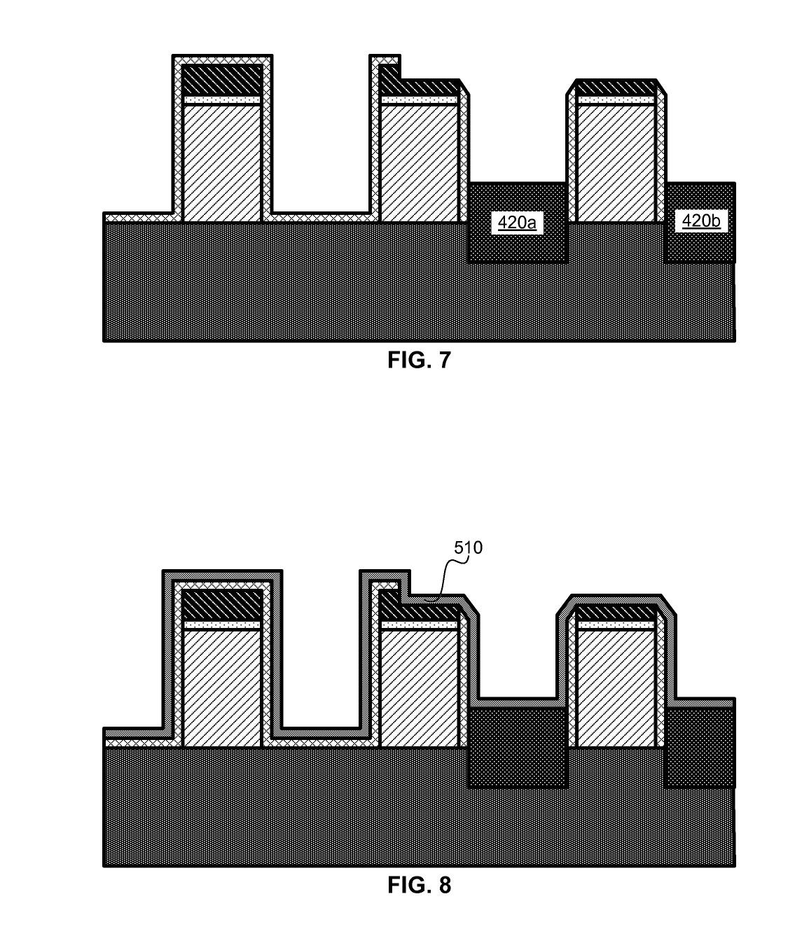

Referring to FIG. 7, source/drains 420a and 420b are formed by, for example, epitaxially growing silicon-containing material in source/drain recess regions 410a and 410b (FIG. 6), respectively. Depending on the nature of the semiconductor device being formed, this material may be, for example, silicon, silicon-germanium, or silicon carbide, and may be doped or undoped.

Referring to FIG. 8, a second spacer material layer 510 is deposited over the surface of the structure of FIG. 7. Second spacer material layer 510 may be made of materials including, but not limited to, silicon nitride, silicon oxide, silicon carbide and may be 2 nm to 100 nm thick, preferably 2 nm to 50 nm.

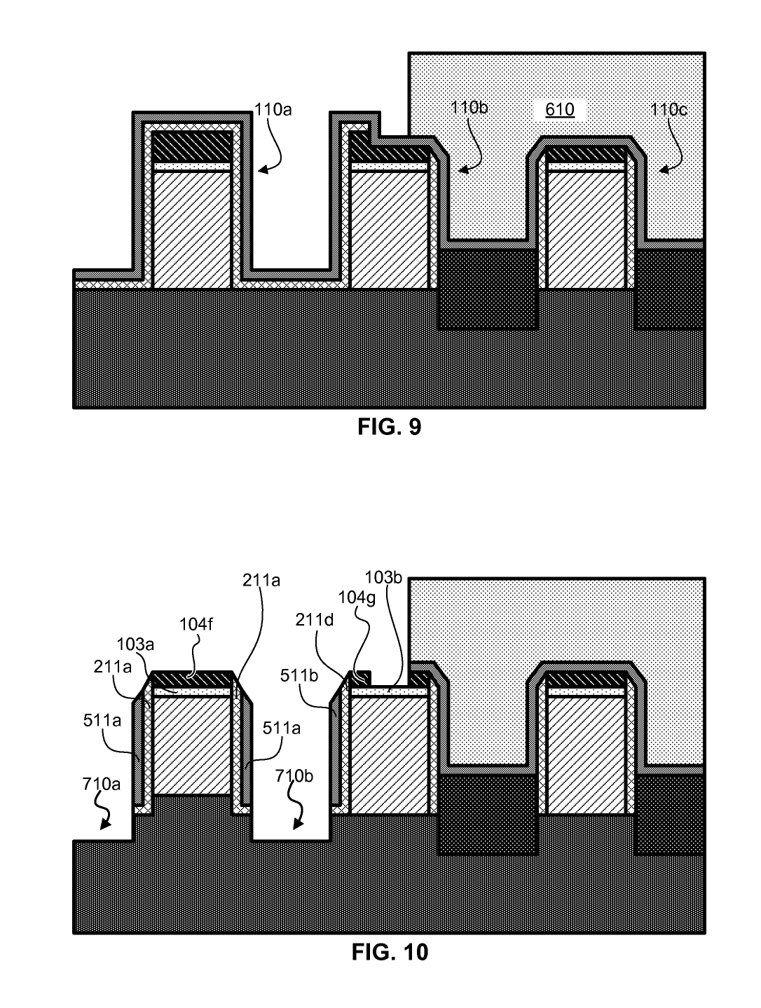

Referring to FIG. 9, a second photoresist layer 610 is deposited over the right side of the structure of FIG. 8, so that gate 110c is fully covered and gate 110b is partially covered by second photoresist layer 610. Because sacrificial gate 102b is protected by gate seal 103b, less protective layers are required to prevent exposing sacrificial gate 103a. Therefore, the region covered by second photoresist layer 610 may not overlap the region previously covered by first photoresist layer 310 in FIGS. 3-4. In one embodiment, gate 110b is less than fifty percent covered. Gate 110a remains exposed.

Referring to FIG. 10, the exposed portion of the structure of FIG. 9 is etched, using, for example, RIE, to form spacers 211a, 211d, 511a and 511b, and source/drain recess regions 710a and 710b. During the etching process, the exposed portion of second spacer material layer is removed. Spacers 211a and 211d are formed on the sides of gates 110a and 110b, respectively, by removing material from portion 220. Spacers 511a and 511b are formed on the sides of gates 110a and 110b, respectively, by removing material from second spacer material layer 510. Material may also be removed from hard masks 104a and 104d (FIG. 6), forming hard masks 104f and 104g, respectively. The etching process used in FIG. 10 should be capable of selectively etching through the materials of second spacer material layer 510, portion 220, and semiconductor substrate semiconductor substrate 101 typically oxides, nitrides, and silicon-containing semiconductor materials, while substantially not impacting the material of gate seals 103a and 103b. In one embodiment, a reactive ion etching process using a gas mixture containing CH₃F, C₄F₈ and C₄F₆ at electrostatic chuck temperature below 100 degrees Celsius may be used. Due to the selective nature of the etching process, should the etching process etch completely through hard masks 104a or 104d (FIG. 6), sacrificial gates 102a and 102b are protected by gate seals 103a and 103b, respectively.

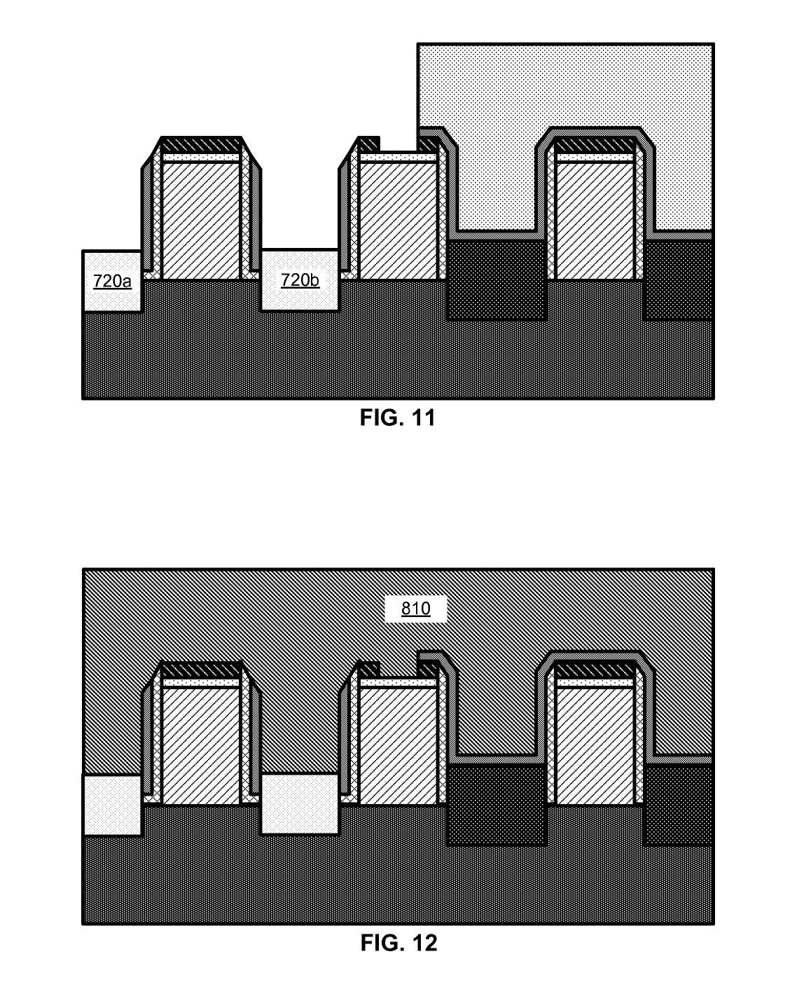

Referring to FIG. 11, source/drains 720a and 720b are formed by, for example, epitaxially growing silicon-containing material in source/drain recess regions 710a and 710b (FIG. 10), respectively. Depending on the nature of the semiconductor device being formed, this material may be, for example, silicon, silicon-germanium, or silicon carbide, and may be doped or undoped.

Referring to FIG. 12, an inter-level dielectric (ILD) layer 810 is deposited over the surface of the structure of FIG. 11. ILD layer 810 may be made of materials including, but not limited to, silicon oxide, silicon nitride, and silicon carbide, and is thick enough to fully cover the surface of the structure of FIG. 11. In some embodiments, ILD layer 810 may also contain at least one inter-level dielectric liner made of material such as silicon nitride (not shown) deposited before the bulk ILD material. A person of ordinary skill in the art will understand how to incorporate any such liner without departing from the scope of the disclosed embodiments.

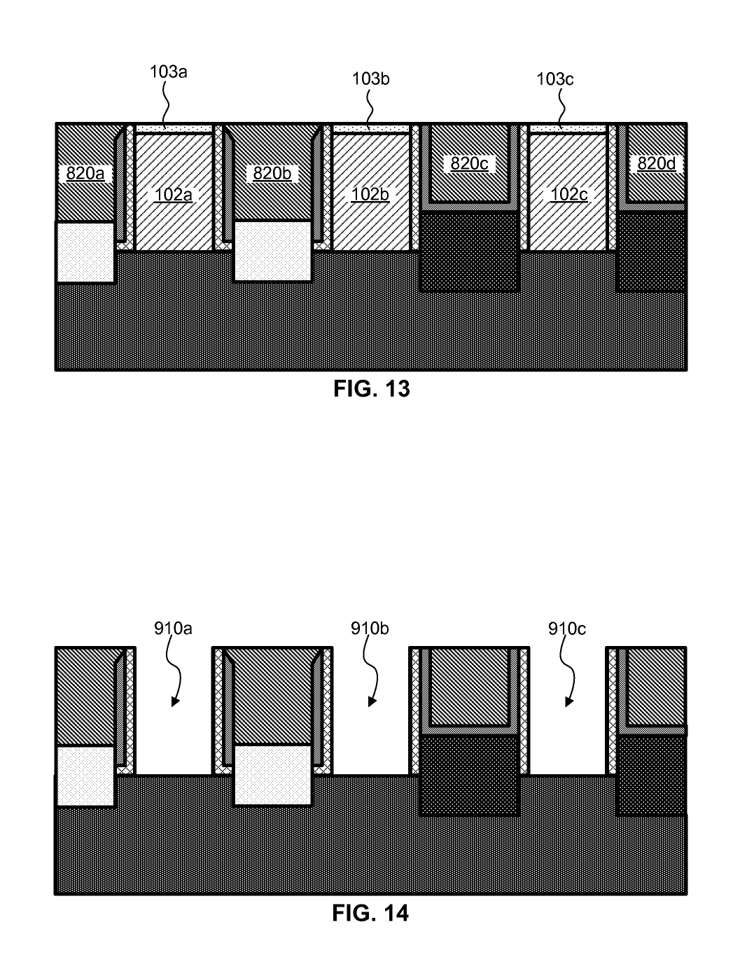

Referring to FIG. 13, the structure of FIG. 12 is planarized using, for example, chemical-mechanical planarization (CMP), with gate seals 103a-103c serving as a polishing stop layer. The remaining portions of ILD layer 810 form ILD segments 820a-820d.

FIGS. 14-16 depict a replacement metal gate process. Referring to FIG. 14, gate seals 103a-103c (FIG. 13) and sacrificial gates 102a-102c (FIG. 13) are removed. Gate seals 103a-103c may be removed by an etching process, for example wet etching or RIE. The etching process should selectively remove the material of the gate seals 103a-103c while not substantially removing the surrounding materials. In one embodiment, this etching may be accomplished using a RIE process with a gas mixture including BCl₃ and Cl₂ at an electrostatic chuck temperature above 200 degrees Celsius. Sacrificial gates 102a-102c (FIG. 13) are removed by any known method, including, for example, an RIE process capable of selectively removing silicon or a hydrofluoric acid-containing wet etch to form regions 910a-910c. As depicted in FIG. 15, various metals and/or dielectrics are then deposited in regions 910a-910c (FIG. 14), and on the top surface of the structure of FIG. 14. The depicted embodiment includes a gate dielectric layer (not shown), a first work-function metal 921, a second work-function metal 922, and a metal film 923. First work-function metal 921 may be made of, for example, titanium nitride, tantalum, tantalum nitride, or titanium-aluminum and may be 1 nm to 50 nm thick, preferably 1 nm to 10 nm. Second work-function metal 922 may be made of, for example, titanium nitride, tantalum, tantalum nitride, or titanium-aluminum and may be 1 nm to 50 nm thick, preferably 1 nm to 10 nm. Metal film 923 may be made of, for example, aluminum or tungsten. Other embodiments may include more or less metal layers depending on the application and types of device or devices being formed. The composition of each metal layer may also vary and the process of selecting the material for each metal layer is known in the art. As depicted in FIG. 16, the structure of FIG. 15 is then planarized using chemical-mechanical planarization or any other known method to remove any excess metal from the top surfaces of ILD segments 820a-820d. The planarization process results in metal gates 930a-930c, each gate including first metal layers 921a-921c, second metal layers 922a-922c, and third metal layers 923a-923c, respectively. The structure is then ready for contact formation and/or fill processes.

As discussed above, the inclusion of the gate seals made of a high-k material accomplishes two things. First, it protects the sacrificial gates during the source/drain recess formation process. Exposing the sacrificial gates during source/drain formation may allow epitaxial growth on the sacrificial gates during source/drain formation and therefore introduce defects into the device. Inclusion of a gate seals avoids the possibility of over-etching and exposing the sacrificial gates and therefore allows for thin spacer deposition and underlapped protective layers, resulting in reduced gate aspect-ratio at the time of source/drain formation and ILD deposition. Second, the remaining gate seals provide for a convenient etch-stop layer for planarization after the deposition of the ILD layer. This leads to uniform device height and therefore fewer defects in the contact formation process.

1. A method of manufacturing a semiconductor device comprising:
forming a gate on a semiconductor substrate, wherein the gate comprises a sacrificial gate, a hard mask, and a high-k gate seal between the sacrificial gate and the hard mask, wherein the hard mask and the high-k gate seal are made of different materials;
forming a source/drain near the gate while the gate seal protects the sacrificial gate; and
removing the hard mask using a planarizing process, wherein the gate seal serves as a polishing stop layer.

2. The method of claim 1, wherein forming the gate comprises depositing a gate stack layer comprising a sacrificial gate material layer, a gate protection layer, and a hard mask layer on the semiconductor substrate; and etching the gate stack layer.

3. (canceled)

4. The method of claim 1, wherein the gate seal comprises a material selected from the group consisting of hafnium oxide, hafnium oxynitrate, and aluminum oxide.

5. The method of claim 1, wherein the gate seal is 2 nm to 15 nm thick.

6. The method of claim 1, wherein forming a source/drain near the gate comprises etching in the semiconductor substrate a source/drain recess region near the gate and filling the source/drain recess region with a semiconductor material while the sacrificial gate remains covered by the gate seal.

7. The method of claim 6, wherein etching in the semiconductor substrate a source/drain recess region comprises etching the semiconductor substrate without substantially removing material from the gate seal.

8. The method of claim 6, wherein etching in the semiconductor substrate at least one source/drain recess region comprises etching the semiconductor substrate using a reactive ion etching process with an etch chemistry comprising CH₃F, C₄F₈, and C₄F₆.

9. The method of claim 6, wherein filling the source/drain recess region with a semiconductor material comprises epitaxially growing the semiconductor material in the source/drain region without substantially growing the semiconductor material on the sacrificial gate.

10. (canceled)

11. (canceled)

12. (canceled)

13. A method of manufacturing a semiconductor device comprising:
forming at least one sacrificial gate having sidewalls on a surface of a semiconductor substrate;
protecting the at least one sacrificial gate with a barrier layer formed on the a top surface of the at least one sacrificial gate, wherein the barrier layer comprises a hard mask layer and a high-k gate seal between the hard mask layer and the at least one sacrificial gate, wherein the hard mask layer and the high-k gate seal are made of different materials;
etching at least one source/drain recess region in the semiconductor substrate near the at least one sacrificial gate;
filling the at least one source/drain recess region with a semiconductor material while the sacrificial gate remains covered by the barrier layer; and
removing the hard mask layer using a planarizing process, wherein the gate seal serves as a polishing stop layer.

14. (canceled)

15. The method of claim 13, wherein the gate seal comprises a material selected from the group consisting of hafnium oxide, hafnium oxynitrate, and aluminum oxide.

16. The method of claim 13, wherein the gate seal is 2 nm to 15 nm thick.

17. The method of claim 13, wherein etching at least one source/drain recess region in the semiconductor substrate comprises etching the semiconductor substrate using a reactive ion etching process with an etch chemistry comprising CH₃F, C₄F₈ and C₄F₆.

18. A method of protecting sacrificial gates while forming source/drain regions comprising:
providing a semiconductor substrate having on its surface at least one sacrificial gate;
protecting the at least one sacrificial gate with a hard mask and a high-k protective layer between the at least one sacrificial gate and the hard mask, wherein the hard mask and the high-k protective layer are made of different materials;
etching in the semiconductor substrate at least one source/drain recess region adjacent to the at least one sacrificial gate;
growing at least one silicon-containing source/drain in the at least one source/drain recess region while substantially not growing silicon on the at least one sacrificial gate; and
removing the hard mask layer using a planarizing process, wherein the gate seal serves as a polishing stop layer.

19. The method of claim 18, wherein the high-k protective layer comprises a material selected from the group consisting of hafnium oxide, hafnium oxynitrate, and aluminum oxide.

20. The method of claim 18, wherein removing the high-k protective layer comprises using a reactive ion etching process using a gas mixture comprising BCl₃ and Cl₂ to etch the high-k protective layer.
